(19) United States
(12) Patent Application Publication
(10) Pub. No.: US 2011/0226912 A1
(43) Pub. Date: Sep. 22, 2011

(54) DEVICE FOR ACCOMODATING COMPONENTS OF TELECOMMUNICATION AND DATA SYSTEMS TECHNOLOGY

(75) Inventor: Ralf-Dieter Busse, Hoppegarten Deutschland (DE)

(73) Assignee: ADC GMBH, BERLIN (DE)

(21) Appl. No.: 13/131,572

(22) PCT Filed: Oct. 27, 2009
(86) PCT No.: PCT/EP09/07667

§ 371 Date: May 26, 2011

(30) Foreign Application Priority Data
Nov. 27, 2008 (DE) 10 2008 059 383.4

(51) Int. Cl. H05K 7/14; F16L 3/08

(52) U.S. Cl. 248/65; 248/309.1

(57) ABSTRACT

The invention relates to a device (1) for accommodating components of telecommunication and data systems technology, comprising at least one support (2) which extends in the longitudinal direction and has a cross-section for accommodating ring or fork contacts or arcuate snap-in elements, the cross-section having a contour, wherein at least three points (P1-P4) of the contour lie on a common circle K having a radius R, the contour having an opening angle α of ≦180°, and at least two of the three points lying on the circle having a radius of curvature which is smaller than the radius R.

The invention relates to an apparatus for accommodating components from telecommunications and data technology.

A wide variety of designs of apparatuses for accommodating components from telecommunications and data technology are known.

A known system uses round profiled rods, onto which strips or modules from telecommunications and data technology can be snapped. In this case, two spaced-apart round profiled rods are preferably used, which rods are arranged such that they are spaced apart from one another, the strips or modules correspondingly having two spaced-apart, arcuate snap-action elements. Such a system is known, for example, from EP 0 304 393 A. It is further known to latch strips or modules with ring-shaped or fork-shaped contacts onto the round profiled rods in order to also achieve a connection to ground via the round profiled rods in addition to providing mechanical holding means. The round profiled rods in this case extend in a longitudinal direction and have a circular cross section. The round profiled rods are positioned and held in a vertical or horizontal position via suitable separate holding bodies.

The invention is based on the technical problem of providing an alternative apparatus for accommodating components from telecommunications and data technology.

The solution to the technical problem results from the subject matter having the features of claim 1. Further advantageous configurations of the invention are given in the dependent claims.

In this regard, the apparatus for accommodating components from telecommunications and data technology comprises at least one mount extending in the longitudinal direction with a cross section for accommodating ring-shaped or fork-shaped contacts or arcuate snap-action elements, the cross section having a contour in which at least three points of the contour lie on a common circle K with the radius R, the contour having an opening angle α of less than/equal to 180°, and at least two of the three points lying on the circle having a radius of curvature which is smaller than the radius R. It is noted here that the circle is an imaginary circle. The formation of the contour means that there are at least three contact points between the mount and the component, with the result that secure mechanical fastening and, if desired, a safe connection to ground is achieved. As a result of the radii of curvature of less than the radius R of the circle, it is additionally ensured that the components can rotate sufficiently easily on the contour, in particular in the event of contact being made between metallic fork-shaped or ring-shaped contacts.

All of the advantages of the round profiled rods are therefore essentially retained, but the apparatus has a greater degree of freedom in terms of construction and is therefore also suitable for more compact designs. The apparatus in this case preferably is made from sheet metal.

Preferably, precisely three points of the contour lie on the imaginary circle.

In a further preferred embodiment, the opening angle is greater than 0°, with the result that the contour is open.

In a further preferred embodiment, a holding body adjoins a part of the mount which delimits the opening angle. In this case, it is noted that a holding body can likewise adjoin the mount with a closed contour.

In a further preferred embodiment, the apparatus is designed to have two mounts, which are connected to a common holding body, with further preferably cable fastenings and/or cable guides being arranged on the holding body or the holding body being formed with said cable fastenings and/or cable guides.

In a further preferred embodiment, the apparatus is designed to be integral and further preferably is in the form of a stamped, bent part. As a result, a very compact design can be achieved, with the complete apparatus being only one part. Furthermore, this reduces costs for manufacture and warehousing and simplifies the construction.

The invention will be explained in more detail below with reference to a preferred exemplary embodiment. In the figures:

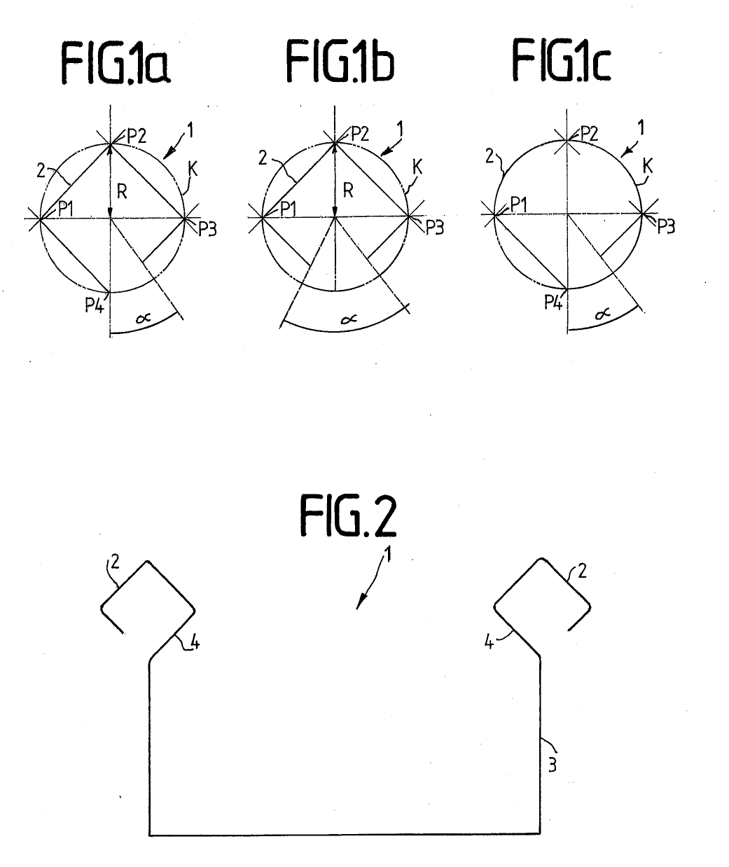

FIG. 1a shows a contour of a cross section of a mount of a first exemplary embodiment,

FIG. 1b shows a contour of a cross section of a mount of a second exemplary embodiment,

FIG. 1c shows a contour of a cross section of a mount of a third exemplary embodiment, and

FIG. 2 shows a cross section through an apparatus with two mounts and a common holding body.

FIG. 1a illustrates a contour of a cross section of a mount 2 of a first embodiment of an apparatus 1 for accommodating components from telecommunications and data technology. In this case, the contour substantially corresponds to a square, with one side being partially removed. In this case, the points P1-P4 lie on a circle K with the radius R, an opening angle α of less than/equal to 180° being set, where, in the example illustrated, α=45°. The radii of curvature of the points P1-P3 of the contour are in this case smaller than the radius R of the circle K. It is noted here that, in the case of a sharp bend at the points P1-P3, there is no radius of curvature when taken in strict mathematical terms. Owing to the fact that these bends are not exactly sharp-edged in sheet-metal technology, however, a correspondingly small real radius of curvature results, and it is thus expressly emphasized that such bends which are in principle sharp-edged are also included in accordance with the invention.

FIG. 1b illustrates a second embodiment, with precisely three points P1-P3 lying on the circle K, an opening angle α of 90° being set. The radii of curvature of all three points P1-P3 are in this case again smaller than the radius R.

Finally, FIG. 1c illustrates a third embodiment, with an infinite number of points lying on the circle K. The points P1 and P3 have a radius of curvature which is smaller than the radius R, with the point P2 and the adjacent points having a radius of curvature which is equal to the radius R. The opening angle α is approximately 45°.

FIG. 2 illustrates the apparatus 1 with two mounts 2 and a common holding body 3, which is U-shaped in cross section. The right-hand mount 2 in this case corresponds to the embodiment shown in FIG. 1a, with the left-hand mount being designed in precisely mirror-inverted fashion. The respectively longer, open limb 4 of the contour in this case merges as an extension with the holding body 3. The holding body 3 has, for example, the shape of a trough, whose side walls are designed to have, for example, cable guides or cable fastenings. It is thus possible for a very compact, integral apparatus 2 to be formed which integrates all of the necessary elements.

Finally it is noted that the radius R of the circle preferably corresponds to the radius of the round profiled rods to be replaced, i.e. is generally 6 mm.

### LIST OF REFERENCE SYMBOLS

1 Apparatus
2 Mount
3 Holding body
4 Limb
K Circle
R Radius
P1-P4 Points
α Opening angle

1. An apparatus for accommodating components from telecommunications and data technology, comprising at least one mount extending in the longitudinal direction with a cross section for accommodating ring-shaped or fork-shaped contacts or arcuate snap-action elements, wherein the cross section has a contour in which at least three points of the contour lie on a common circle K with the radius R, the contour having an opening angle α of less than/equal to 180°, and at least two of the three points lying on the circle having a radius of curvature which is smaller than the radius R.

2. The apparatus as claimed in claim 1, wherein precisely three points lie on the circle K.

3. The apparatus as claimed in claim 1 wherein the opening angle is greater than 0°.

4. The apparatus as claimed in claim 3, wherein a holding body adjoins a part of the mount which delimits the opening angle α.

5. The apparatus as claimed in claim 4, wherein the apparatus is designed to have two mounts, which are connected to a common holding body.

6. The apparatus as claimed in claim 4 wherein cable fastenings and/or cable guides are arranged on the holding body.

7. The apparatus as claimed in claim 4, wherein the apparatus is designed to be integral.

8. The apparatus as claimed in claim 1, wherein the apparatus is in the form of a stamped, bent part.
